(19) United States
(12) Patent Application Publication
(10) Pub. No.: US 2010/0143108 A1
(43) Pub. Date: Jun. 10, 2010

(54) Device for the Protection of Components Having A Flammable Titanium Alloy From Titanium Fire, and Method for the Production Thereof

(75) Inventors: Thomas Uihlein, Dachau (DE); Wolfgang Eichmann, Puchheim (DE); Falko Heutling, Muenchen (DE); Markus Uecker, Muenchen (DE)

Correspondence Address: Davidson, Davidson & Kappel, LLC, 485 7th Avenue, 14th Floor, New York, NY, 10018, US

(73) Assignee: MTU AERO ENGINES GMBH, München (DE)

(21) Appl. No.: 12/449,184

(22) PCT Filed: Jan. 29, 2008
(86) PCT No.: PCT/DE2008/000152

§ 371 Date: Jul. 27, 2009

(30) Foreign Application Priority Data
Feb. 6, 2007 (DE) 10 2007 005 755.7

(51) Int. Cl. F04D 29/54; B32B 15/04; B32B 5/14; C23C 14/34; C23C 16/00; B05D 1/00; F04D 29/38

(52) U.S. Cl. 415/200; 428/457; 428/610; 428/220; 204/192.15; 427/248.1; 427/401; 416/241 R

(57) ABSTRACT

The use of titanium-based materials in the manufacturing of gas turbines, especially of engines, and, in particular, of compressors is made possible in that a device is devised that protects the components (guide vanes, guide vane stages, rotor blades, rotor blade stages) that are subject to the action of titanium fire and/or FODs by employing a layer system that includes at least two layers, is situated on the surface of the components to be protected, and is bonded thereto, as the case may be, via an adhesion-promoting layer is disclosed. The outermost layer is ceramic; the layer that is subjacent thereto is of metallic nature. Additional layers can optionally follow, ceramic and metallic layers alternating with one another. Moreover, a method is provided for producing the device. Through the at least partial use of titanium alloys, in particular for guide vanes of gas turbines, the weight of compressors can be significantly reduced in that the need for the nickel- or steel-based structural materials used under the related art is eliminated in favor of lighter titanium alloys.

Priority is claimed to German Patent Application DE 10 2007 005 755.7, filed Feb. 6, 2007 through international application PCT/DE2008/000152, filed Jan. 29, 2008, the entire disclosures of which are hereby incorporated by reference herein.

### BACKGROUND OF THE INVENTION

The present invention is in the realm of gas-turbine technology, such as power plant or engine technology, and relates, in particular, to components that are encountered in this field. The present invention presents a device for protecting flammable titanium alloys from titanium fire and/or from damage caused by foreign objects.

To optimize the efficiency of a gas turbine, under which engines or also power turbines, for example, are subsumed, the mass of, in particular, the rotating, in the case of mobile units, also the static (non-rotating) elements, should be as small as possible, to ensure that variations in the rotational speed, respectively, in the overall speed of the engine, induce little or no change in the kinetic energy. Particularly in the case of aircraft engines, a relatively low engine weight is desirable, given the same power output, since fuel costs can be thereby saved, for example, or a higher payload is made possible.

The lightweight construction that is becoming increasingly prevalent due to the weight savings in modern compressors leads to in an increased use of components made of titanium alloys. To attain the desired high power outputs and efficiency levels, ever greater operating pressures and temperatures are required. However, at or above a specific temperature and pressure level, what is generally referred to as a titanium fire can occur. Since titanium burns very easily due to its very high affinity for oxygen, it is no longer possible to extinguish such a fire and, within a very short period of time—8 to 10 seconds—and at temperatures of up to 2500° C., it can lead to considerable damage to the components, in extreme cases, even to total engine loss.

A titanium fire can be caused, inter alia, by damage to the blades, heavy rubbing of the turbine blades against the casing, or also by storage-related damage.

To significantly minimize the chance of a titanium fire occurring—that is mostly caused by the rubbing of blade tips against the casing—, in the simplest case, flammable (titanium-containing) mass can be removed from the critical area and be replaced by steel or nickel alloys.

To protect the mostly very highly stressed components, as well as to enhance the attainable precision, coatings are also frequently used in the art. In an engine, for example, these coatings typically include layers against wear, corrosion, hot-gas corrosion and hot-gas oxidation, titanium fire, as well as layers for minimizing the gap between the rotor and stator, as well as thermal insulation layers. In the area of the compressor, layers are used most notably for protecting against titanium fire and for erosion protection.

Coatings of layers several millimeters thick can be provided in the area of the casing wall, in particular. These layers can include plasma-sprayed oxide-ceramic layers, for example.

To minimize the damage caused by erosion, either especially hard carbidic layers in a metal matrix, such as tungsten carbide-cobalt or chromium carbide in a nickel-chromium matrix, are used, for example, or the protection is provided by the protective layer's capacity to mitigate the kinetic energy of the erosive particles with the aid of plastic deformation, as is possible through the use of appropriate lacquers, for example.

The blades, in particular, the guide vanes of the especially thermally loaded high-pressure compressors themselves, are mostly manufactured from what is generally referred to as “superalloys.” Superalloys are characterized as highly alloyed materials of a complex composition (iron, nickel, platinum, chromium or cobalt-based having additives of the elements Co, Ni, Fe, Cr, Mo, W, Re, Ru, Ta, Nb, Al, Ti, Mn, Zr, C and B) for high-temperature applications. However, in comparison to titanium, which is at least used in forged form in low-pressure compressors, their density is approximately twice as great and thus their weight is correspondingly high. Another possibility for using titanium in highly stressed parts of the engine is derived from its alloy containing aluminum (TiAl). This option is especially used in the production of rotor blades.

U.S. Pat. No. 5,114,797 (Uihlein et al.) discusses a three-layer coating for protecting against titanium fire that is composed of a metallic adhesion-promoting layer, a heat-insulating intermediate layer of oxidic nature, as well as of a titanium fire-inhibiting metallic coating. As a metallic adhesion-promoting layer, a nickel-aluminum alloy is discussed, in particular; as an intermediate layer, a zirconium-oxide layer; and, as a protective coating, aluminum and/or aluminum oxide.

U.S. Pat. No. 5,006,419 (Grunke et al.) likewise describes aluminum as a protective layer for the structural components. The protection mechanism is achieved in this case by vaporizing the aluminum.

The publication U.S. Pat. No. 5,114,797 cited from the related art utilizes precisely three layers, the adhesion-promoting layer being mandatory. An especially wear-resistant or corrosion-inhibiting effect of the coating is not known.

The aluminum coating discussed in U.S. Pat. No. 5,006,419 is likewise locally removed, particularly in response to locally active thermal loads, so that premature damage (recrystallization, combustion) to the substrate material can potentially arise.

Due to the high strength and low specific weight of titanium, it is desirable that the material titanium be used as extensively as possible in the manufacturing of movable and fixed elements of gas turbines, particularly in the area of the compressor as well and, in this regard, most notably in the area of the guide vanes. In this context, it would be beneficial to ensure that the material not be able to be damaged by what is commonly known as erosion and/or FODs (foreign object damage; damage caused by foreign objects), nor by what is generally referred to as titanium fire, which occurs, for example, as the result of moving parts rubbing against stationary parts made of titanium, respectively that it be protected as best possible.

### SUMMARY OF THE INVENTION

It is, therefore, an object of the present invention to devise a device for protecting components having a flammable titanium alloy from titanium fire and/or from damage caused by foreign objects, that is able to be produced simply and cost-effectively, but nevertheless reproducibly and reliably in terms of process.

This objective is achieved by a device for protecting components having a flammable titanium alloy from titanium fire and/or from damage caused by foreign objects, in particular, for protecting blades of a turbo engine, wherein the device for protecting the components has a layer system having at least two layers, and the outer layer of the layer system is composed of a ceramic layer, and the layer that is subjacent thereto of a metallic layer; or wherein the device for protecting the components layer system having at least one layer, the layer of this layer system, respectively, the outer layer of this layer system having ceramic and metal and being formed as a graduated layer and, in fact, in such a way that the ceramic content in this (outer) layer increases from the inside outwards, and the metal content decreases from the inside outwards; or wherein the components are protected by a layer system having at least two layers, the layer system having a high melting point, being nonflammable and erosion-resistant. The object is further achieved by a system having at least one component that is made of titanium or of a titanium alloy or that includes titanium, in particular, compressor rotor blades or compressor guide vanes of a gas turbine, and a device for protecting this at least one component from titanium fire and/or damage caused by foreign objects, wherein this device is designed in accordance with one of the preceding claims, and the layer system that includes this device, respectively that is formed by the same, is applied to this component, the outer layer of the layer system being constituted of a ceramic layer. Another object of the present invention is to provide a method for producing the aforementioned device or system wherein the layer system is applied using a coating method, in particular, vapor deposition and/or sputtering.

In one embodiment of the invention, the outer layer of the layer system, i.e., the ceramic layer, is preferably a titanium-free or low titanium-concentration multicomponent system. It is especially preferred that the layer that is subjacent thereto be composed of a titanium-free or low titanium-concentration metallic layer.

The device according to the present invention is used for protecting highly stressed components, in particular, turbine components such as guide vanes or rotor blades, from external influences, in particular from titanium fire and from damage caused by foreign objects, by employing a layer system that includes at least two layers and that is permanently bonded to the component.

The layer system preferably has a high melting point and/or is nonflammable. In one especially advantageous design, the layer system is—in particular, additionally—also erosion-resistant.

An important advantage of the present invention is that it makes it possible for light, titanium-based materials to be used in the area of highly stressed components, in particular, in the realm of gas turbine manufacturing and, in this regard, most notably in the area of the compressor guide vanes. A significant reduction in the weight of compressors is thereby achieved.

The combination of metallic and ceramic layers provided in one preferred form makes it possible for the ceramic layers to be adapted in terms of expansion properties to the metallic substrate material. In addition, the metallic layers prevent the propagation of any cracks potentially occurring in the ceramic layers. The ceramic layers, in turn, protect the entire system from damage caused by excessively high temperatures. These layers also provide a protection against metallic contact of the substrate material in the case of FODs.

By using a plurality of successive combinations of one ceramic and one metallic layer in each case, it is possible to further increase the sustainable volume of ablation in the event of damage.

Even in the case of a complete, localized ablation of the protective layer, the remaining coated surfaces prevent a spreading of a heat-induced combustion, respectively, of a burning of titanium-based substrate material, i.e., what is commonly referred to as a titanium fire.

Since the coating may be very thin, it does not influence or only marginally influences the weight, the aerodynamics and the vibrational strength of the components protected by it.

The present invention is directed to a device for protecting flammable titanium alloys from titanium fire and/or from damage caused by foreign objects (FODs). It achieves this objective by providing a protective layer system that is composed of at least two layers and that envelops the entire component or portions thereof. In this context, the component may be a guide vane or a rotor blade of an axial turbo engine, for example, a guide vane or a rotor blade of a compressor stage.

The most important properties of these layers are the lack of flammability, and the high or very high melting point thereof. In addition, at least the outermost layer of the layer system according to the present invention has an erosion-inhibiting effect. This outermost layer is advantageously composed of a ceramic layer, in particular, of a non-titanium-based multicomponent system. A chromium nitride layer, an aluminum nitride layer or a chromium aluminum nitride layer constitute especially preferred variants of the ceramic layer.

The layer that follows the ceramic layer and is covered by the same is constituted, in particular, of a metallic layer, in particular of a non-titanium-based metal or metal alloy layer. A chromium, nickel or aluminum layer, or alloys thereof, for example, constitute especially preferred variants of the metallic layer.

In their shared combination, these two layers constitute the simplest variant of the device according to the present invention, which, in the following, is designated as “basic composite.”

In another advantageous practical implementation of the present invention, the layer system includes a series of at least two basic composites. An important advantage of this kind of structure is derived from the provision of an increased ablation mass, which results in an enhanced security against burnthrough or breakdown of the layer system.

In another variant of the present invention, an adhesion-promoting layer is additionally provided between the layer system to be protected and the substrate material.

In another preferred variant, instead of an abrupt transition between some or all layers of the layer system, a graduated transition may be provided, for example, in the form of CrAl—(CrAl)₁₋ₓ—CrAlN.

In one especially preferred variant of the device according to the present invention, the ceramic layer(s), in particular, is/are dimensioned to prevent the subjacent titanium alloy of the substrate material from undergoing incipient fusion or fusion for the duration of at least one titanium fire.

In another especially preferred variant of the device according to the present invention, the layer thicknesses of the layers are dimensioned in such a way that the overall thickness of the layer system does not exceed a few, in particular three, millimeters; and, in one especially preferred specific embodiment, it is smaller than one millimeter, especially smaller than 3/10 millimeter, especially smaller than 2/10 millimeter, especially smaller than 1/10 millimeter.

All variants of the layer system may either cover a component in its entirety or merely portions thereof. Likewise possible are combinations of different variants, for example, those from a basic composite, together with those from a plurality of basic composites, with or without an adhesion-promoting layer. If an entire assembly is located in a region that requires protection from titanium fire and/or FODs, then all parts of the assembly, some parts, only one part, or only areas of a part are protected by the device according to the present invention. Any desired combinations of protected parts, respectively of part areas are also possible. If, for example, the assembly is a compressor, then the guide vanes, the individual guide vane stages, the rotor blades, or the individual rotor blade stages and/or areas of the same may be optionally protected by the device according to the present invention.

Common to all of the described specific embodiments is that the aerodynamics and the vibrational strength of the components protected by the device according to the present invention are not affected or are only negligibly affected.

In one especially preferred variant of the device according to the present invention, this permits refurbishing in the case of a repair.

In addition, in accordance with the present invention, a corresponding method is provided for applying a layer system according to the present invention to the surfaces to be protected. In this context, it may be provided, for example, that the layer system be applied by thermal spraying and/or by flame spraying and/or by vacuum plasma spraying and/or by EB-PVD (electron beam physical vapor deposition; electron beam-induced deposition from the vapor phase), and/or by an electrochemical method and/or by sputtering and/or by vapor deposition (PVD) and/or by PVD (physical vapor deposition) and/or by arc evaporation (CARC).

### BRIEF DESCRIPTION OF THE DRAWINGS

Other refinements of the present invention are explained in greater detail in the following, and preferred exemplary embodiments of the present invention are described with reference to the figures, without being limited thereto, which show:

FIG. 1 a structure of a layer system 1, which is composed of a ceramic outer layer 1a and of a subjacent metallic bonding layer 1b (“basic composite”) that is disposed on a substrate material 2;

FIG. 2 a structure of a layer system 1 as recited in FIG. 1, which, in addition, includes an adhesion-promoting layer 3 that is situated between the inner layer of the layer system from FIG. 1 and substrate material 2;

FIG. 3 a structure of a layer system 1 according to FIG. 1 which is composed of a plurality of mutually alternating ceramic layers 1a and metallic layers 1b (two basic composites); and

FIG. 4 a layer system according to FIG. 3 whose outer layers have been damaged by the impact of foreign objects or by contact with liquid titanium and which exhibits cracks 4 and 5; however, the innermost layer being undamaged, and the substrate material thus being protected.

### DETAILED DESCRIPTION

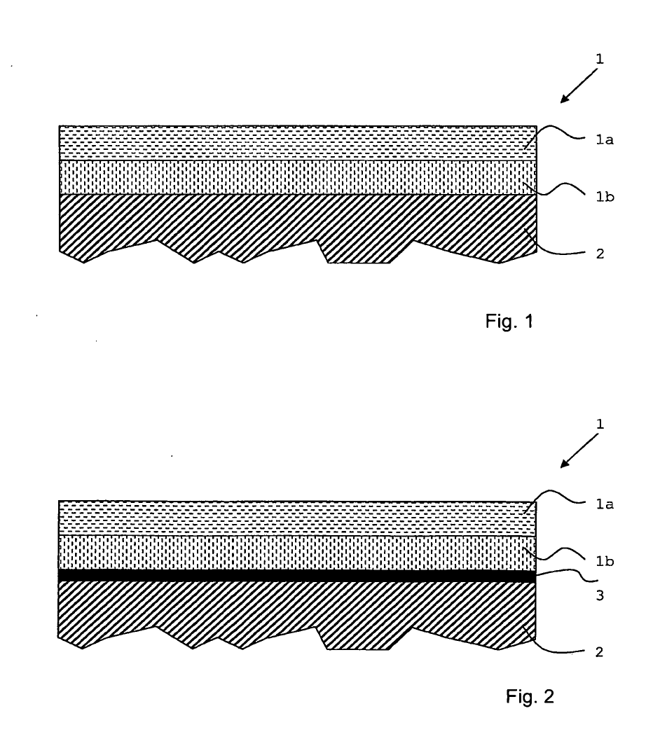

FIG. 1 shows the cross section through a layer system 1 that is composed of an external ceramic layer 1a and of a metallic layer 1b that is subjacent thereto. This composite, which, in the following, is designated as “basic composite,” is applied, for its part, to a substrate material 2, of which only the near-surface portion is shown, and is permanently bonded thereto. The basic composite has the task of protecting substrate material 2 from external influences, in particular, from excessively high temperatures and from FODs, as well as of averting a risk of titanium fire, respectively, of at least preventing or impeding the same when titanium, respectively, a titanium alloy is used as substrate material 2.

This is achieved in that external ceramic layer 1a has a poor thermal conductivity, as well as an extremely high melting point. Therefore, it keeps the heat away from metallic layer 1b that is subjacent thereto and prevents the same, respectively, substrate material 2 from melting or melting away, at least for the duration of a titanium fire. Moreover, it provides an especially effective erosion resistance. Finally, it prevents a first metallic contact with substrate material 2 in the event that metallic FODs occur.

Since, under certain conditions, ceramic layer 1a has a distinctly different expansion coefficient than substrate material 2, it is not disposed directly thereon, where it could easily chip off; rather it is held by metallic layer 1b, to which it is permanently bonded and which functions, inter alia, as a thermal-expansion compensation layer.

Since, in accordance with the present invention, both layers a and b are nonflammable and have a high melting point, they are not able to ignite, burn and/or melt, either at normal or elevated operating temperatures.

In accordance with the present invention, the thickness and composition of the layers may be dimensioned in such a way that the laminar composite offers an effective protection against titanium fire and FODs and, at the same time, does not entail any negative effects on the vibrational strength of the protected component.

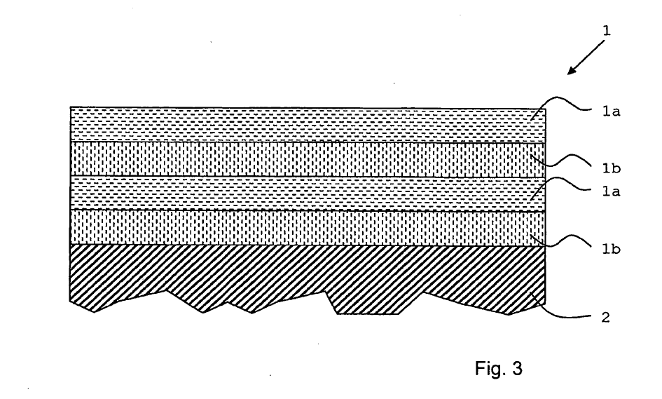

FIG. 2 shows a layer system 1 according to the present invention, according to FIG. 1, composed of a ceramic layer 1a and a metallic layer 1b, that, in addition, is underlaid with an adhesion-promoting layer 3 and is permanently bonded thereto. Adhesion-promoting layer 3 has the task of improving the adhesion between metallic layer 1b and substrate material 2 when metallic layer 1b otherwise does not adhere firmly enough to substrate material 2.

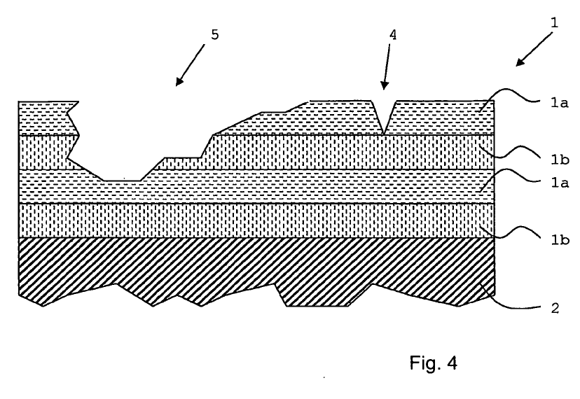

FIG. 3 shows a layer system 1 according to the present invention that is made up of two basic composites from FIG. 1. Accordingly, it is composed of an outer ceramic layer 1a, followed by a metallic layer 1b, another ceramic layer 1a, and, finally, a last metallic layer 1b. In accordance with the present invention, all layers are permanently bonded together and to substrate material 2. Such a multilayer structure enhances the protective action in that a correspondingly higher volume is provided that may be ablated in the case of damage or a titanium fire.

FIG. 4 shows a layer system comparable to that of FIG. 3 and illustrates another task of metallic layers 1b. Besides the functions named above, it has the task of preventing the propagation of cracks 4 and 5, as occur, for example, in response to the thermoshock-type stress produced when titanium fire occurs during contact with molten titanium. These types of cracks may also be caused, for example, by the vibratory loading of the components or by the occurrence of FODs on the components.

Even in the case of a complete, local abrading of layer system 1 (not shown in FIG. 4), the still intact areas of layer system 1 prevent or impede the spreading of a titanium fire.

The present invention is not limited in its practical implementation to the preferred exemplary embodiment indicated above. Rather, a number of variants which utilize the described approach are conceivable, even in the context of fundamentally different executions.

1 to 12 (canceled)

13. A device for protecting components having a flammable titanium alloy from titanium fire and/or from damage caused by foreign objects, in particular, for protecting blades of a turbo engine, comprising:
a layer system having at least two layers, and the outer layer of the layer system composed of a ceramic layer, and the layer that is subjacent thereto composed of a metallic layer.

14. A device for protecting components having a flammable titanium alloy from titanium fire and/or from damage caused by foreign objects, in particular, for protecting blades of a turbo engine, comprising:
a layer system having at least one outer layer having ceramic and metal and being formed as a graduated layer in such a way that a ceramic content in the outer layer increases from the inside outwards, and a metal content decreases from the inside outwards.

15. The device as recited in claim 13,
wherein the components are protected by the layer system, the layer system having a high melting point, being nonflammable and erosion-resistant.

16. The device as recited in claim 14,
wherein the components are protected by the layer system, the layer system having a high melting point, being nonflammable and erosion-resistant.

17. The device as recited in claim 13,
the ceramic layer alternating with one metallic layer in each instance.

18. The device as recited in claim 13,
wherein the layer system includes an adhesion-promoting layer situated between the innermost layer of the layer system and the substrate material.

19. The device as recited in claim 13,
wherein a transition between some or all of the layers is graduated.

20. The device as recited in claim 13,
wherein the ceramic layer prevents, alone or in conjunction with the other ceramic layers, the subjacent titanium alloys from undergoing incipient fusion or fusion for the duration of at least one titanium fire.

21. The device as recited in claim 14,
wherein the ceramic layer prevents, alone or in conjunction with the other ceramic layers, the subjacent titanium alloys from undergoing incipient fusion or fusion for the duration of at least one titanium fire.

22. The device as recited in claim 13,
wherein the layer system has a maximum thickness that is smaller than 0.1 mm.

23. The device as recited in claim 14,
wherein the layer system has a maximum thickness that is smaller than 0.1 mm.

24. The device as recited in claim 13,
wherein the layer system is situated on some or all of the components or areas of the same; these includes the group of the guide vanes, of the individual guide vane stages, of the rotor blades, or of the individual rotor blade stages of a compressor.

25. The device as recited in claim 14,
wherein the layer system is situated on some or all of the components or areas of the same; these includes the group of the guide vanes, of the individual guide vane stages, of the rotor blades, or of the individual rotor blade stages of a compressor.

26. The device as recited in claim 13,
wherein the layer system does not influence the vibrational strength of the base element, and the layer system can be refurbished in the case of a repair.

27. The device as recited in claim 14,
wherein the layer system does not influence the vibrational strength of the base element, and the layer system can be refurbished in the case of a repair.

28. A system having at least one component that is made of titanium or of a titanium alloy or that includes titanium, in particular, compressor rotor blades or compressor guide vanes of a gas turbine, and having a device for protecting this at least one component from titanium fire and/or damage caused by foreign objects, comprising
a layer system as recited in claim 13 applied to the component.

29. A method for producing the device as recited in claim 13,
wherein the layer system is applied using a coating method.

30. The method as recited in claim 29,
wherein the coating method is vapor deposition and/or sputtering.
